(19) United States
(12) Patent Application Publication
(10) Pub. No.: US 2025/0294932 A1
(43) Pub. Date: Sep. 18, 2025

(54) DISPLAY DEVICE

(71) Applicant: AUO Corporation, Hsinchu City (TW)

(72) Inventors: Chih-Tsung Lee, Hsinchu City (TW); Yen-Huei Lai, Hsinchu City (TW); Kuei-Ning Cheng, Hsinchu City (TW); Chih-Yu Yu, Hsinchu City (TW); Chih-Hung Wu, Hsinchu City (TW); Cheng-Hao Chang, Hsinchu City (TW); Wan-Tsang Wang, Hsinchu City (TW)

(73) Assignee: AUO Corporation, Hsinchu City (TW)

(21) Appl. No.: 18/902,987

(22) Filed: Oct. 1, 2024

(30) Foreign Application Priority Data
Mar. 12, 2024 (TW) 113108921

(51) Int. Cl. H01L 33/58; H01L 25/16

(52) U.S. Cl. CPC H10H 20/855; H01L 25/167

(57) ABSTRACT

A display device comprises a substrate, a display element layer, a pixel and a light guide structure. The display element layer is disposed on the substrate. The pixel is disposed on the display element layer. The light guide structure is disposed on the display element layer. The substrate is a stretchable substrate, the display element layer comprises a first opening, and the light guide structure is bonded to the substrate through the first opening.

### CROSS-REFERENCE TO RELATED APPLICATION

This application claims the priority benefit of Taiwan application serial no. 113108921, filed on Mar. 12, 2024. The entirety of the above-mentioned patent application is hereby incorporated by reference herein and made a part of this specification.

### BACKGROUND

### Technical Field

The invention relates to a display device.

### Description of Related Art

When using fabric layer as a surface of display device, the screen resolution of the display device is easily affected by the weaving method and mesh size of the fabric layer. For example, when the display device is stretched, a situation of secondary misalignment between the fabric layer and the display device easily happen, and the screen resolution of the display device is decreased. Therefore, how to effectively maintain the screen resolution of the display device has become a very important part of the design of the display device when using fabric layer as the surface of display device.

### SUMMARY

This disclosure provides a display device with good screen resolution.

According to an embodiment of the present disclosure, a display device comprises a

substrate, a display element layer, a pixel and a light guide structure. The display element layer is disposed on the substrate. Pixel is disposed on the display element layer. The light guide structure is disposed on the display element layer. The substrate is a stretchable substrate, the display element layer comprises a first opening, and the light guide structure is bonded to the substrate through the first opening.

Based on the above, in the display device of the embodiment of the present disclosure, the display element layer is disposed on the substrate, the pixel is disposed on the display element layer, and the light guide structure is disposed on the display element layer, and the display element layer comprises a first opening. The substrate is a stretchable substrate, and the light guide structure is bonded to the substrate through the first opening. In this way, since the light guide structure is bonded to the substrate, the screen resolution of the display device is not easily decreased when the substrate is deformed due to external force. Therefore, the screen resolution of the display device can be greatly improved.

### BRIEF DESCRIPTION OF THE DRAWINGS

FIG. 1 is a schematic three-dimensional diagram of a display device according to an embodiment of the present disclosure.

FIG. 2A is a schematic top view of the display device of FIG. 1.

FIGS. 2B to 2D are schematic cross-sectional diagrams in FIG. 2A along the I-I′ line.

FIG. 2E is a schematic top view of the display device of FIG. 1 according to an embodiment of the present disclosure.

FIG. 2F is a schematic cross-sectional diagram in FIG. 2E along the line I-I′.

FIG. 3 is a schematic three-dimensional diagram of a display device according to an embodiment of the present disclosure.

FIGS. 4A and 4B are schematic top views of the display device in FIG. 3.

FIGS. 4C and 4D are schematic cross-sectional diagrams in FIG. 4B along the I-I′ line.

### DESCRIPTION OF THE EMBODIMENTS

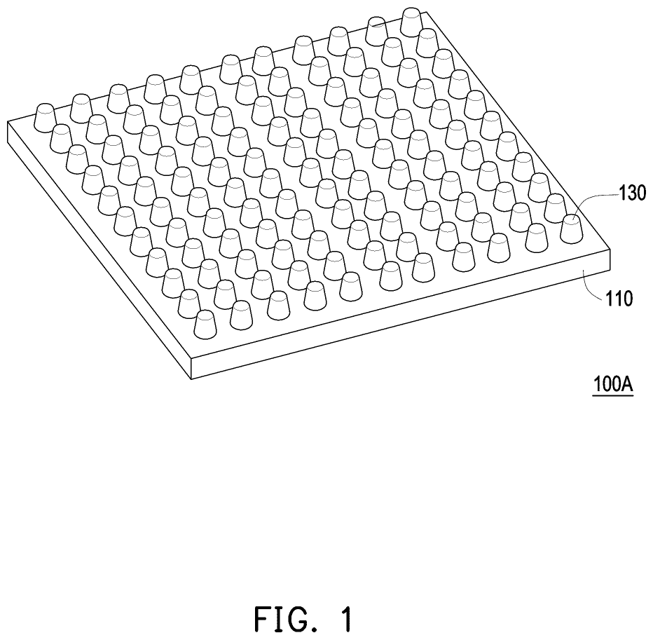

FIG. 1 is a schematic three-dimensional diagram of a display device according to an embodiment of the present disclosure. The display device 100A in FIG. 1 comprises a substrate 110 and a light guide structure 130.

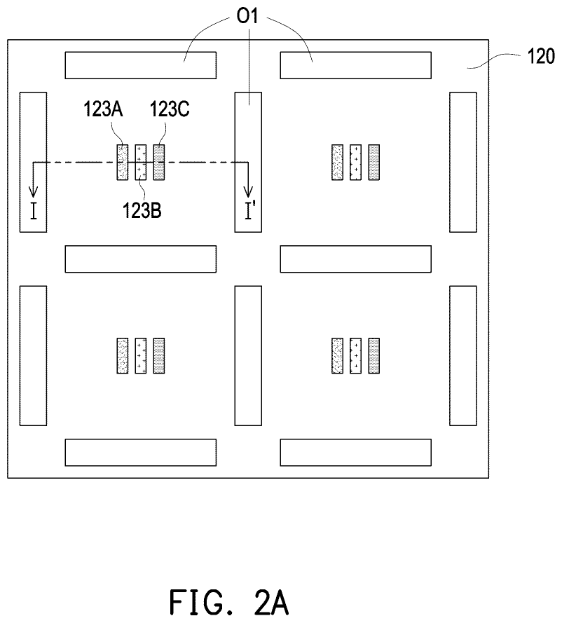

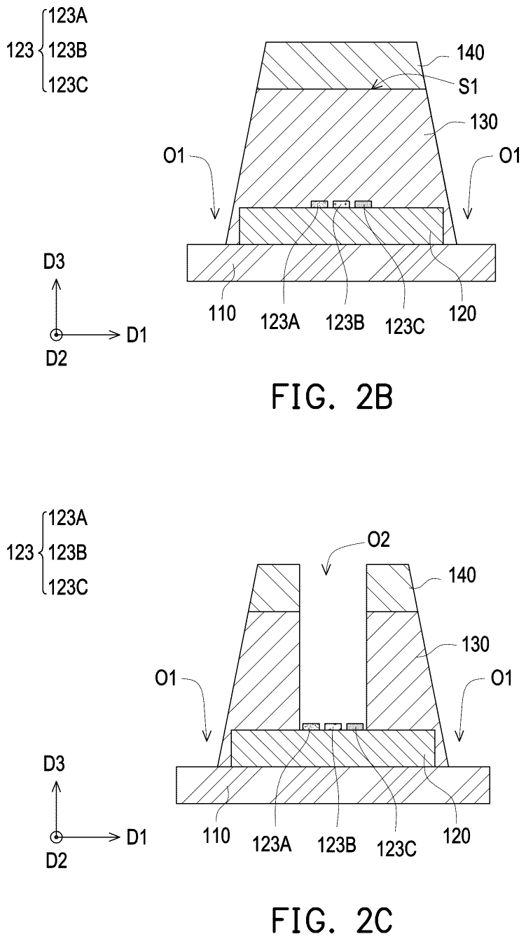

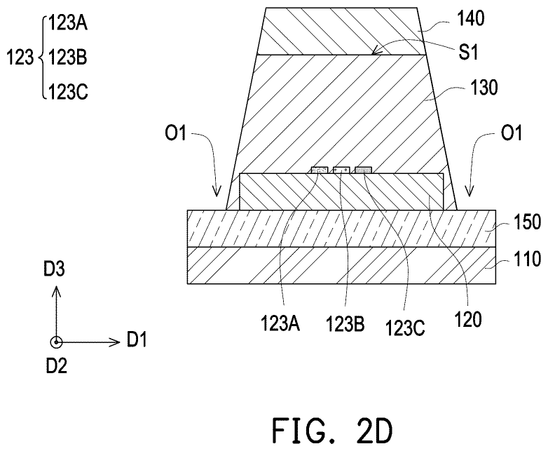

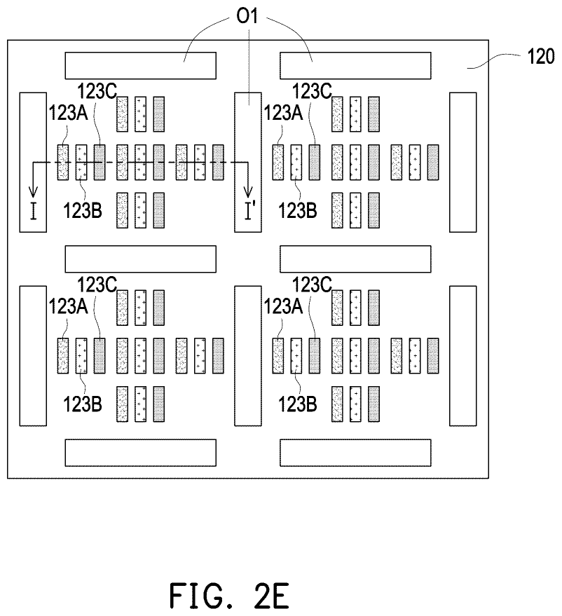

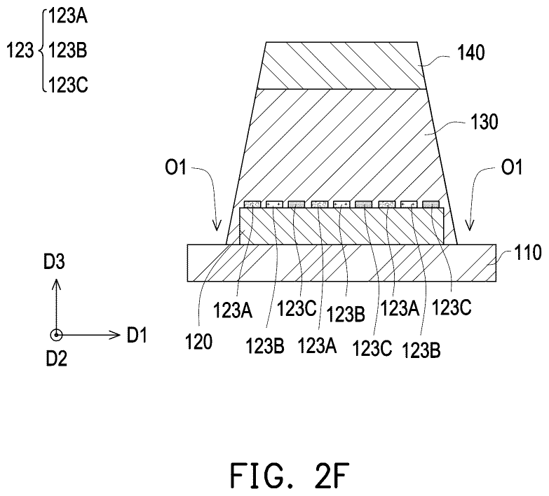

FIG. 2A is a schematic top view of the display device of FIG. 1. The display device in FIG. 2A comprises a display element layer 120, a plurality of pixels 123 and a plurality of first openings O1.

FIG. 2B is schematic cross-sectional diagrams in FIG. 2A along the I-I′ line. The cross-sectional structure shown in FIG. 2B can be applied to one or more of the plurality of pixels 123 in FIG. 2A, or all of the plurality of pixels 123 in the display device 100A. As shown in FIG. 2B, the display device 100A comprises a substrate 110, a display element layer 120, a pixel 123, and a light guide structure 130.

There may be circuit (not shown) on the substrate 110, and the plurality of pixels 123 are disposed in an array on the substrate 110, for example, along the first direction D1 (e.g., X direction) and the second direction D2 (e.g., Y direction), but the disclosure is not limited thereto. Each of the plurality of pixels 123 may comprise a first sub-pixel 123A, a second sub-pixel 123B and a third sub-pixel 123C. In some embodiments, each sub-pixel comprises a light-emitting element, such as a light-emitting diode. The light emitting diodes may comprise, for example, organic light emitting diode (OLED), submillimeter light emitting diode (mini LED), micro light emitting diode (micro LED) or quantum dot light emitting diodes (for example, QLED, QD LED), fluorescence, phosphorescence or other suitable materials, and the materials can be arbitrarily disposed and combined, but the disclosure is not limited thereto. In some embodiments, the light-emitting element may be a light-emitting chip, and the sub-pixel may be coupled to the substrate 110 in the form of a chip on board (COB). That is, the light-emitting chip serving as the sub-pixel may be electrically connected to the circuit of the substrate 110. In some embodiments, each sub-pixel may comprise a light-emitting chip as a light-emitting element and a packaging material that encapsulates the light-emitting chip, and each sub-pixel may be coupled to the substrate 110 in the form of a package on board (POB). In some embodiments, the the pixel 123 comprises the plurality of sub-pixels, for example, the first sub-pixel 123A, the second sub-pixel 123B and the third sub-pixel 123C, and the plurality of sub-pixels can be encapsulated in the same encapsulation structure by encapsulation materials and the plurality of sub-pixels is coupled to the substrate 110 in the form of a package on board (POB). In addition, although this embodiment takes as an example that the pixel 123 comprises three sub-pixels (that is, the first sub-pixel 123A, the second sub-pixel 123B and the third sub-pixel 123C), but the disclosure is not limited thereto. In other embodiments, the pixel 123 may have a plurality of sub-pixels comprising two, three, four, five or other quantities.

As shown in FIG. 2B, in the display device 100A, the pixel 123 comprises a first sub-pixel 123A, a second sub-pixel 123B, and a third sub-pixel 123C, and the first sub-pixel 123A, the second sub-pixel 123B, and the third sub-pixel 123C are disposed on the substrate 110. In this embodiment, the display device 100A further comprises a display element layer 120, and each of the plurality of sub-pixels (such as the first sub-pixel 123A, the second sub-pixel 123B and the third sub-pixel 123C) can be coupled to the substrate 110 through the display element layer 120. In this embodiment, the display element layer 120 may be conductive solder, such as alloy solder. In other embodiments, the display element layer 120 may comprise wiring materials, such as metal wiring.

The substrate 110 can be a circuit board, an active element substrate, or other plate-like structures that can be configured to provide driving signals and/or power to the pixels 123 and can support the pixels 123. In some embodiments, when the substrate 110 is a circuit board, the substrate 110 may comprise a plurality of conductive circuit layers and a plurality of insulating layers configured to isolate the plurality of conductive circuit layers, but the disclosure is not limited thereto. Each of the plurality of sub-pixels can be coupled to the substrate 110 through the display element layer 120 and is electrically connected to the substrate 110. In some embodiments, the plurality of sub-pixels (such as the first sub-pixel 123A, the second sub-pixel 123B and the third sub-pixel 123C) are light-emitting diodes, and the plurality of sub-pixels have pairs of electrodes. FIG. 2B only schematically presents the plurality of sub-pixels coupled to substrate 110.

In this embodiment, the three sub-pixels in the pixel 123 have different luminescent colors. The three sub-pixels in pixel 123 can be the first sub-pixel 123A, the second sub-pixel 123B and the third sub-pixel 123C, respectively. The first color pixel 123A, the second sub-pixel 123B and the third color sub-pixel 123C respectively have different luminescent colors. For example, the first color pixel 123A, the second sub-pixel 123B and the third color sub-pixel 123C can be respectively red sub-pixel, blue sub-pixel and green sub-pixel, but the disclosure is not limited thereto. In other embodiments, the luminescent color of the sub-pixel may comprise red, green, blue, yellow, cyan or other colors. In some embodiments, the sub-pixel may comprise a light-emitting element (e.g., a light-emitting diode) and the luminescent color of the sub-pixel may be determined by the light-emitting element. In other embodiments, the plurality of sub-pixels may further comprise light conversion elements (such as quantum dot layers) and/or color filter elements, and the luminescent color of the sub-pixel is determined by the light-emitting element, light conversion element, and color filter element. The luminescent colors of the plurality of sub-pixels are determined by one or more of the light-emitting elements, light conversion elements, or color filter elements. In some embodiments, all of the plurality of pixels 123 in the display device 100A may have the same quantity of sub-pixels, but the disclosure is not limited thereto.

In this embodiment, the substrate 110 may comprise an elastic material, so that the substrate 110 is a stretchable substrate. The light guide structure 130 is disposed on the display element layer 120. The light guide structure 130 can cover the pixel 123. In addition, the display element layer 120 comprises a first opening O1, and the light guide structure 130 can be bonded to the substrate 110 through the first opening O1. In this way, since the light guide structure 130 is bonded to the substrate 110, the plurality of sub-pixels in pixel 123 will not easily displaced when the display device suffers from external forces, that is, the plurality of sub-pixels in the pixel 123 relative to the substrate 110 move toward the first direction D1 or the second direction D2. In this way, a situation of misalignment between sub-pixels in pixel 123 will not easily happen when the display device suffers from external forces. Therefore, the screen resolution of the display device can be greatly improved.

The light guide structure 130 further comprises an outer layer 140 disposed on a surface S1 of the light guide structure 130. The outer layer 140 may comprise different materials, such as soft material, so that when the user touches the display device, he can first touch the outer layer 140 of the light guide structure 130, thus making the display device have a good tactile impression.

As shown in FIG. 2C, the light guide structure 130 also comprises a second opening O2, and the pixel 123 is disposed in the second opening O2. When the light guide structure 130 covers the pixel 123, the second opening O2 of the light guide structure 130 properly exposes the pixel 123, and at the same time, the pixel 123 is stably disposed in the second opening O2. In this way, since the light guide structure 130 is bonded to the substrate 110 and the pixel 123 is stably disposed in the second opening O2, the plurality of sub-pixels in pixel 123 will not easily be displaced when the display device suffers from external forces, that is, the plurality of sub-pixels in the pixel 123 relative to the substrate 110 move toward the first direction D1 or the second direction D2. In this way, a situation of misalignment between sub-pixels in pixel 123 will not easily happen when the display device suffers from external forces. Therefore, the screen resolution of the display device can be greatly improved.

As shown in FIG. 2D, in some embodiments, the display device 100A may also comprise a first adhesion layer 150, which is disposed between the display element layer 120 and the substrate 110. The display element layer 120 comprises a first opening O1 and a light guide structure 130. The first opening O1 is bonded to the first adhesion layer 150. In this way, since the light guide structure 130 is bonded to the substrate 110 and the first adhesion layer 150 is bonded to the substrate 110, the plurality of sub-pixels in pixel 123 will not be easily displaced when the display device suffers from external forces, that is, the plurality of sub-pixels in the pixel 123 relative to the substrate 110 move toward the first direction D1 or the second direction D2. In this way, a situation of misalignment between sub-pixels in pixel 123 will not easily happen when the display device suffers from external forces. Therefore, the screen resolution of the display device can be greatly improved. It should be noted that the first adhesion layer 150 shown in FIG. 2D is only an example. The light guide structure 130 of the present disclosure can be bonded to the first adhesion layer 150 through the first opening O1, and the light guide structure 130 can also be bonded to the first adhesion layer 150 through the first opening. O1. Therefore, the display device can provide a variety of structures to meet different application requirements.

FIG. 2E is a schematic top view of the display device of FIG. 1 according to an embodiment of the present disclosure. FIG. 2F is a schematic cross-sectional diagram in FIG. 2E along the line I-I′. The difference between FIG. 2E and FIG. 2A is that the pixel 123 can be a plurality of pixels 123, which are respectively disposed toward the first direction D1 or the second direction D2. The light guide structure 130 is disposed on the display element layer 120 and covers the plurality of pixels 123. When the three sub-pixels in the pixel 123 are respectively red, green and blue sub-pixels, the arrangement of sub-pixel can be selected from, for example, one of the following color sequences: red-green-blue, blue-green-red, red-blue-green, green-blue-red, green-red-blue and blue-red-green without being limited to the color sequence shown in FIG. 2A. In some embodiments, any two of the above color sequences can be selected to implement sub-pixel arrangement of adjacent two of the plurality of pixels 123, which helps to alleviate or improve the color shift situation of the display device 100A. Therefore, the light guide structure 130 in the display device 100A can cover a plurality of pixels 123, and each pixel 123 can have sub-pixels in different orders, which can greatly improve the screen resolution of the display device.

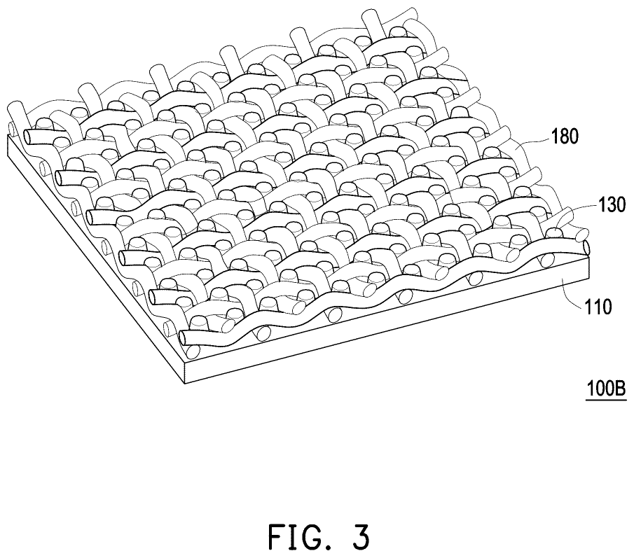

FIG. 3 is a schematic three-dimensional diagram of a display device according to an embodiment of the present disclosure. The display device 100B of FIG. 3 comprises a substrate 110, a light guide structure 130 and a fabric layer 180.

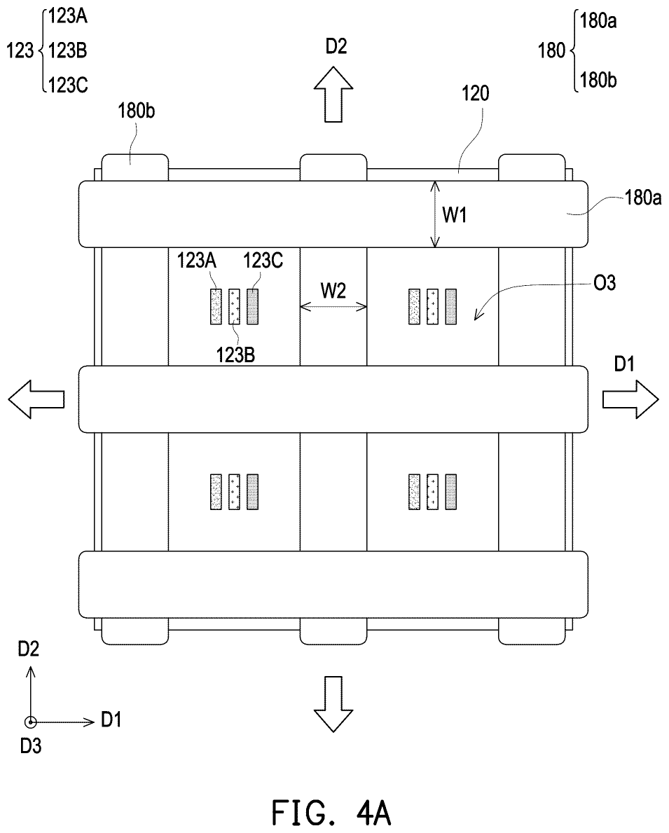

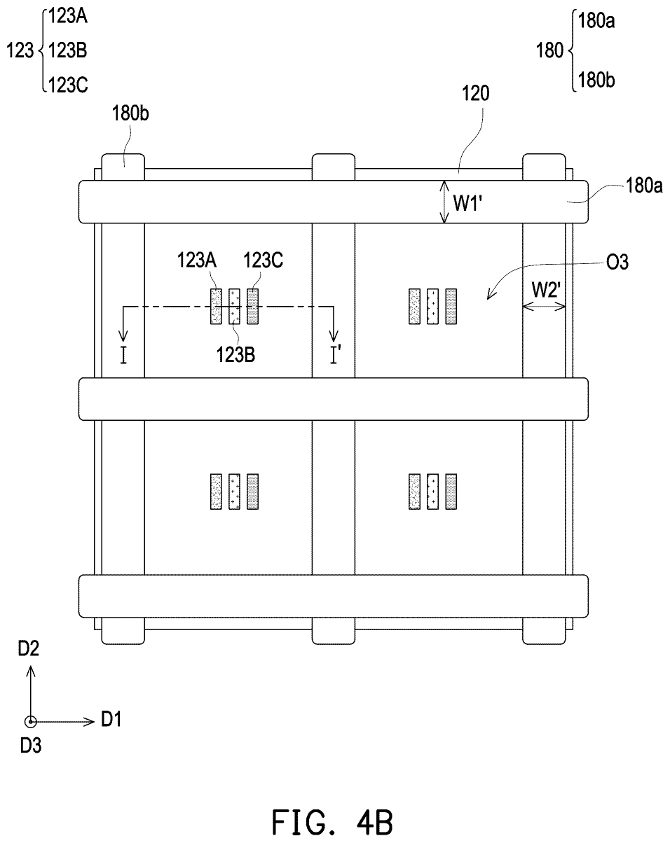

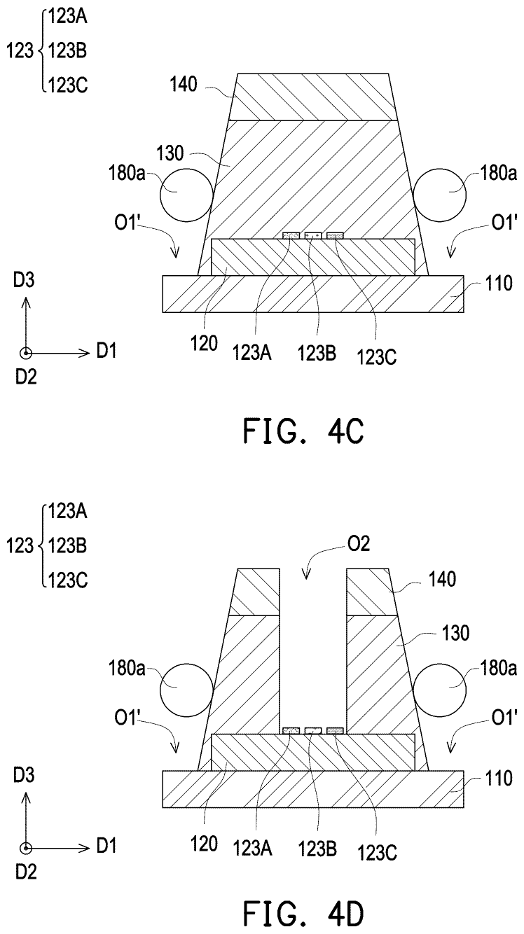

FIGS. 4A and 4B are schematic top views of the display device in FIG. 3. FIG. 4C is schematic cross-sectional diagrams in FIG. 4B along the I-I′ line.

The difference between the display device 100B and the display device 100A is that the display device 100B also comprises a fabric layer 180, which is disposed on the display element layer 120. The fabric layer 180 can be a stretchable material, such as thermoplastic polyurethane (TPU), polyurethane (PU), silicone (Silicone), polyethylene (Polyethylene, PE), thermoplastic elastomer (Thermoplastic elastomers (TPE) or polyimide (PI), etc., the stretch rate range of the fabric layer 180 is, for example, in the range of 10% to 800%, and the preferred stretch rate is 100-600%.

Please refer to FIG. 4A and FIG. 4B. The fabric layer 180 comprises a third opening O3, and the light guide structure 130 is disposed in the third opening O3. In detail, the fabric layer 180 has a plurality of third openings O3, and the plurality of light guide structures 130 in the display device 100B can be disposed in the plurality of third openings O3 of the fabric layer 180. The ratio range of the projected area of the light guide structure 130 on the substrate 110 and the projected area of the third opening O3 on the substrate 110 is, for example, 10% to 150%, preferably 60% to 120%. The ratio of the height of the fabric layer 180 along the third direction D3 to the height of the light guide structure 130 along the third direction D3 is, for example, 10%-200%, preferably 50%-80%. For example, if the height of the fabric layer 180 along the third direction D3 is 1 mm, the height of the light guide structure 130 along the third direction D3 may be 0.5 mm to 0.8 mm. Moreover, if the ratio of the height of the fabric layer 180 along the third direction D3 to the height of the light guide structure 130 along the third direction D3 is 100%-150%, the height of the light guide structure 130 is more than the height of the fabric layer 180, and the structure for the light guide structure 130 along the third direction D3 can protrude from the fabric layer 180.

The fabric layer 180 can be in contact with the light guide structure 130 or not in contact according to the external forces applied in different directions. For example, please refer to FIG. 4A and FIG. 4B. The fabric layer 180 comprises a first portion 180a weaved along the first direction D1 and a second portion 180b weaved along the second direction D2, or various designs comprising different portions weaved along different directions, but the disclosure is not limited thereto.

When the fabric layer 180 is stretched, for example, toward the first direction D1 or toward the second direction D2, the width W1 of the first portion 180a of the fabric layer 180 or the width W2 of the second portion 180b of the fabric layer 180 (as shown in FIG. 4A) will be reduced accordingly into width W1′ or width W2′ (as shown in FIG. 4B), so that both of two portions of the fabric layer 180 originally contacting with the light guide structure 130 becomes, for example, only the first portion 180a of the fabric layer 180 contacting with the light guide structure 130 or only the second portion 180b of the fabric layer 180 contacting with the light guide structure 130. For example, please refer to FIGS. 4A to 4C. The fabric layer 180 is stretched toward the second direction D2, and the width W2 of the second portion 180b is reduced to W2′, while the first portion 180a of the fabric layer 180 is not reduced, so that the first portion 180a and the second portion 180b of the fabric layer 180 contacting with the light guide structure 130 becomes only the first portion 180a of the fabric layer 180 contacting with the light guide structure 130 and the fabric layer 180 will apply uneven force to the light guide structure 130.

Since the light guide structure 130 is bonded to the substrate 110, the plurality of sub-pixels in pixel 123 will not easily be displaced, that is, the plurality of sub-pixels in the pixel 123 relative to the substrate 110 move toward the first direction D1 or the second direction D2. In this way, a situation of misalignment between sub-pixels in pixel 123 will not easily happen when the light guide structure 130 of the display device suffers from uneven forces applied by the fabric layer 180. Therefore, the screen resolution of the display device can be greatly improved.

Please refer to FIG. 4D. In some embodiments, the light guide structure 130 may also comprise a second opening O2 as shown in FIG. 2C, and the pixel 123 is disposed in the second opening O2. When the light guide structure 130 covers the pixel 123, the second opening O2 of the light guide structure 130 properly exposes the pixel 123, and the pixel 123 is stably disposed in the second opening O2. Since the light guide structure 130 is bonded to the substrate 110 and the pixel 123 is stably disposed in the second opening O2, the plurality of sub-pixels in pixel 123 will not easily be displaced (that is, the plurality of sub-pixels in the pixel 123 relative to the substrate 110 move toward the first direction D1 or the second direction D2) when the substrate 110 is deformed due to external force or the fabric layer 180 apply uneven force to the light guide structure 130. In this way, a situation of misalignment between sub-pixels in pixel 123 will not easily happen when the display device suffers from external forces. Therefore, the screen resolution of the display device can be greatly improved.

To sum up, in the display device of the embodiment of the present disclosure, the pixel is disposed on the display element layer, the light guide structure is disposed on the display element layer, the display element layer comprises the first opening, and the light guide structure is bonded to the substrate through the first opening. The substrate is a stretchable substrate. Since the light guide structure is bonded to the substrate, the screen resolution of the display device is not easily decreased when the substrate is deformed due to external force. Therefore, the screen resolution of the display device can be greatly improved.

What is claimed is:

1. A display device, comprising:
a substrate;
a display element layer, disposed on the substrate;
a pixel, disposed on the display element layer; and
a light guide structure, disposed on the display element layer,
wherein the substrate is a stretchable substrate, the display element layer comprises a first opening, and the light guide structure is bonded to the substrate through the first opening.

2. The display device according to claim 1, wherein the light guide structure further comprises an outer layer disposed on a surface of the light guide structure.

3. The display device according to claim 1, wherein the light guide structure further comprises a second opening, and the pixel is disposed in the second opening.

4. The display device according to claim 1, wherein the pixel is a plurality of pixels, and the light guide structure is disposed on the display element layer and covers the plurality of pixels.

5. A display device, comprising:
a substrate;
a display element layer, disposed on the substrate;
a pixel, disposed on the display element layer; and
a light guide structure disposed on the display element layer,
wherein the substrate is a stretchable substrate, and the display device further comprises a first adhesion layer, the first adhesion layer is disposed between the display element layer and the substrate, the display element layer comprises a first opening, and the light guide layer is bonded to the first adhesion layer through the first opening.

6. The display device according to claim 5, wherein the light guide structure further comprises an outer layer, and the outer layer is disposed on a surface of the light guide structure.

7. The display device according to claim 5, wherein the light guide structure further comprises a second opening, and the pixel is disposed in the second opening.

8. A display device, comprising:
a substrate;
a display element layer, disposed on the substrate;
a pixel, disposed on the display element layer;
a light guide structure, disposed on the display element layer; and
a fabric layer, disposed on the display element layer, wherein the fabric layer comprises a third opening, and the light guide structure is disposed in the third opening,
wherein the substrate is a stretchable substrate, the display element layer comprises a first opening, and the light guide structure is bonded to the substrate through the first opening.

9. The display device according to claim 8, wherein the light guide structure further comprises an outer layer, and the outer layer is disposed on a surface of the light guide structure.

10. The display device according to claim 8, wherein the light guide structure further comprises a second opening, and the pixel is disposed in the second opening.

11. The display device according to claim 8, wherein the pixel is a plurality of pixels, and the light guide structure is disposed on the display element layer and covers the plurality of pixels.
